(19) United States
(12) Patent Application Publication
(10) Pub. No.: US 2026/0091972 A1
(43) Pub. Date: Apr. 2, 2026

(54) MEMS VIBRATOR

(71) Applicant: ROHM CO., LTD., Kyoto (JP)

(72) Inventors: Martin Wilfried HELLER, Kyoto (JP); Toma FUJITA, Kyoto (JP); Daisuke NISHINOHARA, Kyoto (JP); Hideaki HASHIMOTO, Kyoto (JP); Shiyu LIU, Fukuoka (JP); Jiaxu WU, Fukuoka (JP); Tamio IKEHASHI, Fukuoka (JP)

(73) Assignee: ROHM CO., LTD., Kyoto (JP)

(21) Appl. No.: 19/340,214

(22) Filed: Sep. 25, 2025

(30) Foreign Application Priority Data
Sep. 27, 2024 (JP) 2024-169007

(51) Int. Cl. B81B 3/00; H03H 9/02

(52) U.S. Cl. CPC B81B 3/0081; H03H 9/02448; B81B 2201/0271; B81B 2203/0118; B81B 2203/0163; B81B 2203/0307; B81B 2203/0315; B81B 2203/04; B81B 2207/07

(57) ABSTRACT

A MEMS vibrator includes a substrate having a first primary surface and a second primary surface disposed on the opposite side of the first primary surface. The substrate has a cavity recessed from the first primary surface to the second primary surface. A vibrating body is disposed inside the cavity. The vibrating body extends linearly in a first direction along the plane in a plan view of the first primary surface, and vibrates in a second direction that intersects with the first direction along the plane. A plurality of supports disposed inside the cavity support the vibrating body from the second direction at a plurality of supporting positions arranged along the first direction at a certain interval.

### CROSS REFERENCE TO RELATED APPLICATION

This application is based upon and claims the benefit of priority of the prior Japanese Patent Application No. 2024-169007, filed on Sep. 27, 2024, the entire contents of which are incorporated herein by reference.

### TECHNICAL FIELD

The present disclosure relates to a MEMS vibrator.

### BACKGROUND ART

International Publication No. WO2005/011116 discloses a MEMS (micro electromechanical system) resonator that includes a substrate, an input electrode disposed on the substrate, and a vibrating electrode disposed above the input electrode with a space therebetween such that the vibrating electrode and the input electrode face each other. The vibrating electrode is a thin film layer such as a polycrystalline silicon film or metal film formed by a thin film deposition method. When a prescribed voltage is applied to the vibrating electrode and a high-frequency signal is input into the input electrode, the electrostatic force generated between the vibrating electrode and the input electrode causes the vibrating electrode to vibrate in the thickness direction.

### BRIEF DESCRIPTION OF THE DRAWINGS

FIG. 1 is a plan view of a MEMS vibrator according to an embodiment of the present disclosure.

FIG. 2 is an enlarged view of an area near the vibrating electrode illustrated in FIG. 1.

FIG. 3 is a cross-sectional view along the line III-III of FIG. 2.

FIG. 4 is an enlarged view of an area near the fixed electrode illustrated in FIG. 1 after the thermal oxidation process.

FIG. 5 is a diagram illustrating the operation of the MEMS vibrator illustrated in FIG. 1.

FIG. 6 is a diagram similar to FIG. 5 according to a modification example of the embodiment.

FIG. 7 is a diagram similar to FIG. 2 according to another modification example of the embodiment.

FIG. 8 is a diagram similar to FIG. 4 according to yet another modification example of the embodiment.

### DETAILED DESCRIPTION OF EMBODIMENTS

Below, a MEMS vibrator according to an embodiment of the present disclosure will be explained with reference to the appended drawings. The descriptions below essentially are mere examples, and do not intend to limit the present disclosure as well as the applications and usage thereof. The drawings are schematic and the ratio of the respective dimensions and the like differ from the reality.

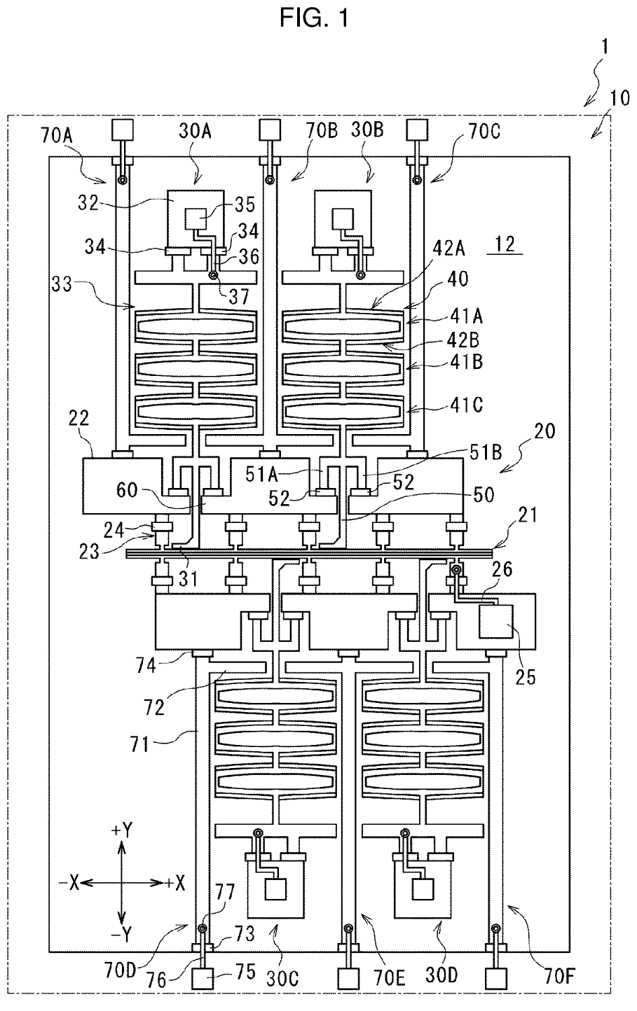

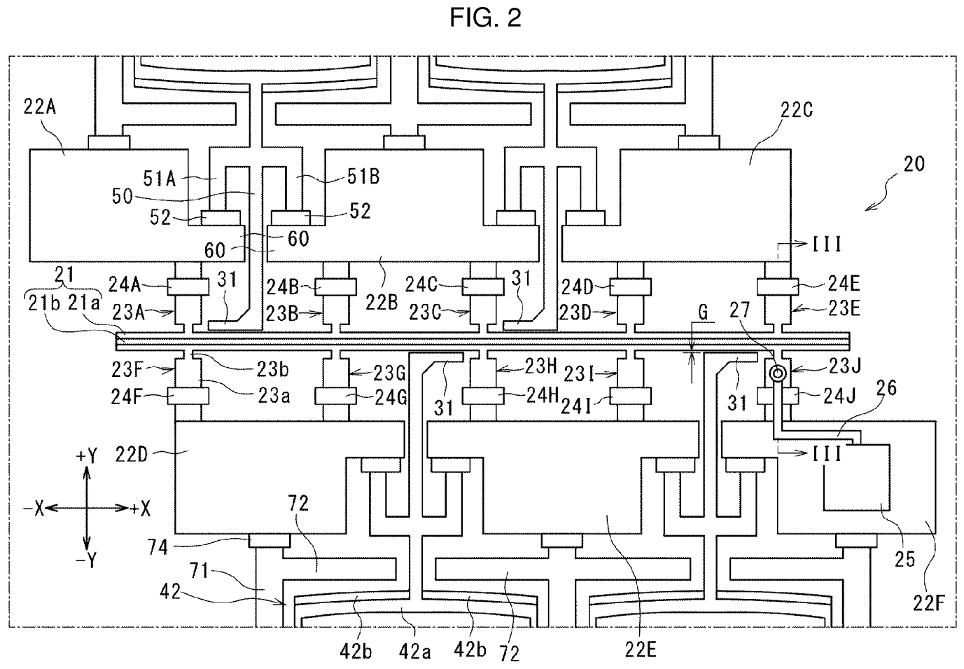

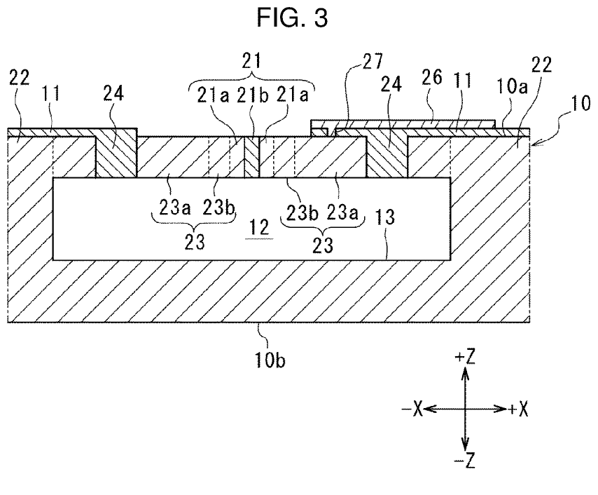

FIG. 1 is a plan view of a MEMS vibrator 1 according to this embodiment. FIG. 2 is an enlarged view of an area near a vibrating electrode 20 illustrated in FIG. 1. FIG. 3 is a cross-sectional view along the line III-III of FIG. 2.

In the following description, for convenience, among the directions along the respective sides of the MEMS vibrator 1 in the plan view of FIG. 1, the left-right direction in FIG. 1 will be referred to as the X direction, and the up-down direction in FIG. 1 will be referred to as the Y direction. Also, the thickness direction of the MEMS vibrator 1 in the cross-sectional view shown in FIG. 3 (the up-down direction in FIG. 3) will be referred to as the Z direction. In particular, in FIG. 1, the right side may be referred to as the +X direction, the left side as the −X direction, the upper side as the +Y direction, and the lower side as the −Y direction. In FIG. 3, the upper side may be referred to as the +Z direction, and the lower side may be referred to as the −Z direction. In this embodiment, the X direction, the Y direction, and the Z direction are orthogonal to each other. The X direction of this embodiment is one example of the first direction of the present disclosure, and the Y direction of this embodiment is one example of the second direction of the present disclosure.

The MEMS vibrator 1 of this embodiment is an electrostatic resonator manufactured by semiconductor microfabrication technology. As illustrated in FIG. 1, the MEMS vibrator 1 includes a substrate 10, a vibrating electrode 20, and a plurality of fixed electrodes 30A to 30D. In the following description, when it is not necessary to particularly distinguish the plurality of fixed electrodes 30A to 30D from each other, one of the plurality of fixed electrodes 30A to 30D may be simply referred to as a fixed electrode 30.

The substrate 10 is a conductive silicon (Si) substrate. The substrate 10 has a first primary surface 10a (see FIG. 3) located on the +Z side and a second primary surface 10b (see FIG. 3) on the −Z side. The first primary surface 10a and the second primary surface 10b each have a planar shape that extend in the X and Y directions. The first primary surface 10a and the second primary surface 10b extend in parallel with each other. On the first primary surface 10a, an insulating layer 11 (see FIG. 3) made of silicon oxide (SiO₂) is deposited. The thickness direction of the substrate 10 coincides with the Z direction. The substrate 10 has a cavity 12 having a rectangular shape in a plan view and recessed from the first primary surface 10a toward the −Z side. The substrate 10 has a bottom wall 13 (see FIG. 3) having a rectangular shape in a plan view that defines the −Z side of the cavity 12.

The vibrating electrode 20 is disposed in the cavity 12. As illustrated in FIG. 2, the vibrating electrode 20 includes a vibrating body 21, a plurality of anchors 22A to 22F, and a plurality of supports 23A to 23J. In the following description, when it is not necessary to particularly distinguish the plurality of anchors 22A to 22F from each other, one of the plurality of anchors 22A to 22F may be simply referred to as an anchor 22. In the following description, when it is not necessary to particularly distinguish the plurality of supports 23A to 23J from each other, one of the plurality of supports 23A to 23J may be simply referred to as a support 23.

When excited by the fixed electrode 30, the vibrating body 21 vibrates in the Y direction at a natural resonant frequency. As shown in FIG. 3, the vibrating body 21 is located on the +Z side of the bottom wall 13 of the substrate 10 and separated therefrom. As illustrated in FIG. 2, the vibrating body 21 has a narrow plate shape extending in the X direction in a plan view. Specifically, the vibrating body 21 has a plate shape with the X direction being the longitudinal direction, the Y direction being the thickness direction, and the Z direction being the short-side direction. The vibrating body 21 is supported from both sides in the Y direction by the supports 23 at a plurality of supporting positions arranged at equal intervals along the X direction.

The vibrating body 21 includes a main body 21a and a deformation stopper 21b disposed within the main body 21a and having a thermal expansion coefficient differing from that of the main body 21a. In this embodiment, the main body 21a is made of conductive silicon, and the deformation stopper 21b is made of silicon oxide. The main body 21a has a rectangular plate shape with the X direction being the longitudinal direction. The deformation stopper 21b crosses the main body 21a in the X direction and the Z direction, and divides the main body 21a in the Y direction. The deformation stopper 21b mechanically connects both sides of the main body 21a that are separated in the Y direction by the deformation stopper 21b. The deformation stopper 21b of this embodiment extends continuously over the entire length of the vibrating body 21 in the X direction.

The anchor 22 supports the vibrating body 21 and the support 23 such that they are separated from the bottom wall 13 on the +Z side. As shown in FIG. 3, the anchor 22 is fixed to the bottom wall 13 of the substrate 10. The anchors 22A to 22C are disposed on the +Y side of vibrating body 21, and the anchors 22D to 22F are disposed on the −Y side of vibrating body 21.

The support 23 supports the vibrating body 21 such that it is separated from the bottom wall 13 of the substrate 10 on the +Z side, while allowing the vibrating body 21 to vibrate. As shown in FIG. 3, the support 23 is located on the +Z side of the bottom wall 13 of the substrate 10, separated therefrom. Also, the support 23 supports the vibrating body 21 over the entire length of the vibrating body 21 in the Z direction. As illustrated in FIG. 2, the support 23 extends in the Y direction. One end of the support 23 is connected to the anchor 22, and the other end of the support 23 is connected to the vibrating body 21. The support 23 is cantilevered by the anchor 22. The support 23 includes a base portion 23a connected to the anchor 22 and a tip portion 23b connected to the vibrating body 21. The width of the tip portion 23b, that is, the dimension in the X direction, is smaller than the width of the base portion 23a, that is, the dimension in the X direction.

A plurality of supports 23A to 23E are disposed on the +Y side of the vibrating body 21, and a plurality of supports 23F to 23J are disposed on the −Y side of the vibrating body 21. The plurality of supports 23A to 23E are arranged at equal intervals along the X direction. The plurality of supports 23F to 23J are arranged such that each one corresponds to one of the plurality of supports 23A to 23E in the X direction. That is, the plurality of supports 23F to 23J are disposed at the same positions in the X direction as the corresponding supports 23A to 23E. The plurality of supports 23A to 23J is constituted of a plurality of pairs of supports 23, 23 that are arranged at equal intervals in the X direction. The vibrating body 21 is supported from both sides in the Y direction by the corresponding pairs of supports 23, 23 at a plurality of supporting positions arranged at equal intervals along the X direction.

The vibrating electrode 20 has a plurality of isolation joints 24A to 24J corresponding one-to-one to the plurality of supports 23A to 23J. In the following description, when it is not necessary to particularly distinguish the plurality of isolation joints 24A to 24J from each other, one of the plurality of isolation joint 24A to 24J may be simply referred to as an isolation joint 24.

The isolation joint 24 crosses the corresponding support 23 in the X direction and the Z direction, and divides it in the Y direction. The isolation joint 24 mechanically connects and electrically isolates both sides of the corresponding support 23 that are separated in the Y direction by the isolation joint 24. The isolation joint 24 electrically isolates the vibrating body 21 from the anchor 22. The isolation joint 24 is disposed at the base portion 23a of the support 23. The isolation joint 24 of this embodiment is made of silicon oxide.

The vibrating electrode 20 includes an electrode pad 25 disposed on the anchor 22F. The electrode pad 25 is electrically connected to a wiring layer 26 extending over the isolation joint 24J. The wiring layer 26 is electrically connected to the vibrating body 21 through a via 27 that penetrates the insulating layer 11 in the Z direction. The electrode pad 25 is electrically connected to the vibrating body 21 through the wiring layer 26 and the via 27. The vibrating body 21 is applied with a constant voltage via the electrode pad 25. The electrode pad 25 is disposed on the insulating layer 11, and the electrode pad 25 and the anchor 22F are electrically insulated from each other by the insulating layer 11.

As illustrated in FIG. 1, the fixed electrode 30 includes an electrode part 31, an anchor 32, and a connecting part 33. The fixed electrodes 30A and 30B are disposed on the +Y side of the vibrating body 21, and the fixed electrodes 30C and 30D are disposed on the −Y side of the vibrating body 21.

The electrode part 31 is made of conductive silicon. The electrode part 31 is separated from the bottom wall 13 of the substrate 10 on the +Z side. The electrode part 31 is disposed to face the vibrating body 21 with space therebetween in the Y direction. The electrode part 31 is a panel shape that extends in the X direction and Z direction. In this embodiment, the electrode parts 31 of the fixed electrodes 30A and 30B function as drive electrodes for vibrating the vibrating body 21, and the electrode parts 31 of the fixed electrodes 30C and 30D function as detection electrodes for detecting the vibration of the vibrating body 21.

The anchor 32 supports the electrode part 31 and the connecting part 33 such that they are separated from the bottom wall 13 on the +Z side. The anchor 32 is fixed to the bottom wall 13 of the substrate 10.

The connecting part 33 connects the electrode part 31 to the anchor 32. The connecting part 33 is separated from the bottom wall 13 of the substrate 10 on the +Z side. The connecting part 33 extends in the Y direction. One end of the connecting part 33 is mechanically connected to the anchor 32 through an isolation joint 34. The anchor 32 is electrically insulated from and mechanically connected to the connecting part 33 by the isolation joint 34. The connecting part 33 is cantilevered by the anchor 32. The other end of the connecting part 33 is connected to the electrode part 31.

The connecting part 33 includes a spring 40 and a beam 50.

The spring 40 can deform elastically in the Y direction. The spring 40 includes a plurality of annular parts 41A to 41C arranged along the Y direction. In the following description, when it is not necessary to particularly distinguish the plurality of annular parts 41A to 41C from each other, one of the plurality of annular parts 41A to 41C may be simply referred to as an annular part 41.

Among the plurality of annular parts 41A to 41C, two annular parts 41, 41 adjacent to each other along the Y direction are connected to each other. The annular part 41 has a rectangular shape in a plan view with the X direction being the longitudinal direction. The annular part 41 has a pair of flexible beams 42A, 42B that define a pair of long sides of the annular part 41. The flexible beam 42A that forms the longer side on the +Y side extends in the X direction and is curved towards the +Y side. The flexible beam 42B that forms the longer side on the −Y side extends in the X direction and is curved towards the −Y side. In the following description, when it is not necessary to particularly distinguish the pair of flexible beams 42A, 42B from each other, one of the pair of flexible beams 42A, 42B may be simply referred to as a flexible beam 42.

As shown in FIG. 2, the flexible beam 42 includes a first portion 42a extending in the X direction and a second portion 42b extending in the X direction and having a thermal expansion coefficient smaller than that of the first portion 42a. In this embodiment, the first portion 42a is made of conductive silicon, and the second portion 42b is made of silicon oxide. In the flexible beam 42A, the second portion 42b is positioned adjacent to the +Y side of the first portion 42a, and in the flexible beam 42B, the second portion 42b is positioned adjacent to the −Y side of the first portion 42a.

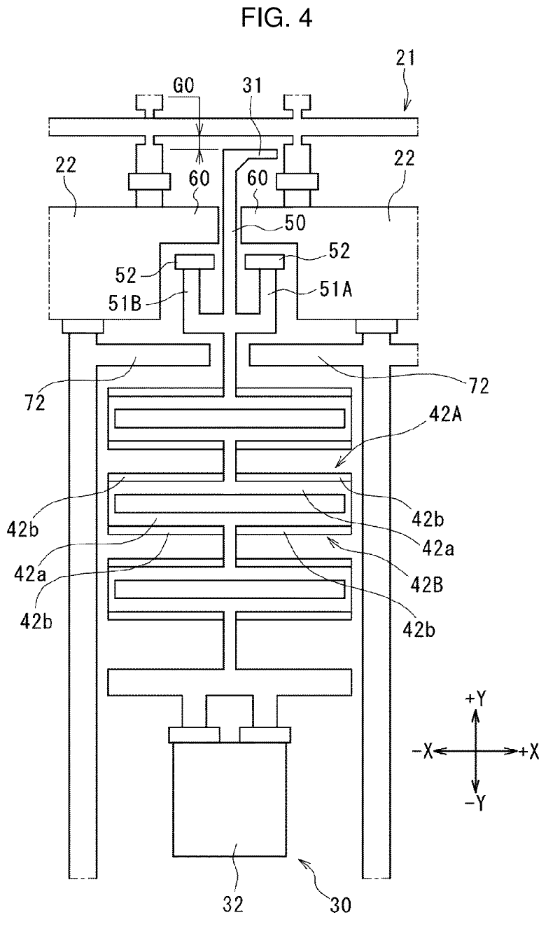

The second portion 42b of the spring 40 is obtained by performing thermal oxidation on the substrate 10. The thermal oxidation of the substrate 10 is carried out at high temperatures (for example, 800° C. to 1200° C.). Referring to FIG. 4, which is an enlarged view of an area near the fixed electrode 30 at the stage where the second portion 42b has been manufactured in the thermal oxidation process, the flexible beam 42 extends linearly in the X direction at the stage shown in FIG. 4. When the MEMS vibrator 1 formed at high temperature as shown in FIG. 4 is cooled to room temperature, due to the difference in thermal expansion coefficient between the first portion 42a and the second portion 42b, thermal stress greater than the thermal stress generated in the second portion 42b is generated in the first portion 42a of the spring 40. As a result, the first portion 42a contracts more than the second portion 42b, the flexible beam 42 is bent as shown in FIG. 1, and the spring 40 as a whole is deformed to extend in the Y direction.

Due to the deformation of the spring 40, the electrode part 31 moves towards the vibrating body 21, transitioning from the state shown in FIG. 4 to the state shown in FIG. 1. This allows the gap G (shown in FIG. 2) between the vibrating body 21 and the electrode part 31 to be narrower than the gap G0 before the spring 40 is deformed. That is, the gap G between the vibrating body 21 and the electrode part 31 can be made narrower than the gap G0 formed between the vibrating body 21 and the electrode part 31 in the etching process for forming the vibrating body 21 and the electrode part 31. As a result, the gap between the vibrating body 21 and the electrode part 31 can be narrowed regardless of the limit of the etching aspect ratio, which improves the performance of the MEMS vibrator 1.

As illustrated in FIG. 1, the beam 50 extends in the Y direction. One end of the beam 50 is connected to the spring 40. The other end of the beam 50 is connected to the electrode part 31. The beam 50 has two protrusions 51A and 51B. In the following description, when it is not necessary to particularly distinguish the respective protrusions 51A and 51B from each other, one of the protrusions 51A and 51B may be simply referred to as a protrusion 51.

The protrusions 51A and 51B protrude from the beam 50 toward both sides in the X direction, respectively, and extend via a bent portion toward the electrode part 31 in the Y direction. That is, the protrusions 51A and 51B are L-shaped in a plan view. An insulator 52 is disposed at the tip of each of the protrusions 51A and 51B. The insulator 52 of this embodiment is made of silicon oxide.

The fixed electrode 30 includes an electrode pad 35 disposed on the anchor 32. The electrode pad 35 is electrically connected to the wiring layer 36 extending over the isolation joint 34. The wiring layer 36 is electrically connected to the electrode part 31 through a via 37 that penetrates the insulating layer 11 in the Z direction. The electrode pad 35 is electrically connected to the electrode part 31 through the wiring layer 36 and the via 37. An AC voltage for driving the vibrating body 21 is applied to the electrode parts 31 of the fixed electrodes 30A and 30B via the electrode pads 35. A constant voltage is applied to the electrode parts 31 of the fixed electrodes 30C, 30D via the electrode pads 35 to detect changes in the capacitance formed between the fixed electrodes 30C, 30D and the vibrating body 21 due to vibration of the vibrating body 21. The electrode pad 35 is disposed on the insulating layer 11, and the electrode pad 35 and the anchor 32 are electrically insulated from each other by the insulating layer 11.

The MEMS vibrator 1 has a restricting part 60 connected to the anchor 22 of the vibrating electrode 20. The restricting part 60 protrudes from the anchor 22 of the vibrating electrode 20 in the X direction. In the state shown in FIG. 4, the restricting part 60 and the protrusion 51 are spaced apart in the Y direction. The restricting part 60 restricts displacement of the electrode part 31 by making contact with the protrusion 51 when the spring 40 of the fixed electrode 30 is deformed by thermal stress and the electrode part 31 moves toward the vibrating body 21. This way, the restricting part 60 maintains a prescribed gap between the electrode part 31 and the vibrating body 21. When the protrusion 51 comes into contact with the restricting part 60, the insulator 52 makes contact with the restricting part 60, ensuring that the electrode part 31 and the anchor 22 of the vibrating body 20 are electrically insulated from each other.

As shown in FIG. 1, the MEMS vibrator 1 includes a plurality of electrostatic chucks 70A to 70F for fixing the fixed electrode 30 to the restricting part 60 by an electrostatic force. In the following description, when it is not necessary to particularly distinguish the plurality of electrostatic chucks 70A to 70F from each other, one of the plurality of electrostatic chucks 70A to 70F may be simply referred to as an electrostatic chuck 70. The electrostatic chuck 70 includes a beam 71 and one or two electrode parts 72.

The beam 71 is made of conductive silicon. The beam 71 extends in the Y direction. One end of the beam 71 is connected to the substrate 10 through an isolation joint 73. The beam 71 is electrically insulated from and mechanically connected to the substrate 10 by the isolation joint 73. The other end of the beam 71 is connected to the anchor 22 of the vibrating electrode 20 through the isolation joint 74. The beam 71 is electrically insulated from and mechanically connected to the anchor 22 by the isolation joint 74. The isolation joints 73 and 74 of this embodiment are made of silicon oxide.

The electrode part (one or two) 72 is made of conductive silicon. The electrode part (one or two) 72 protrudes from the beam 71 toward the X direction. Specifically, the electrostatic chucks 70A and 70D each have one electrode part 72 protruding from the beam 71 toward the +X side. The electrostatic chucks 70B and 70E each have two electrode parts 72 protruding from the beam 71 toward both ways of the X direction. The electrostatic chucks 70C and 70F each have one electrode part 72 protruding from the beam 71 toward the −X side. The electrode parts 72 extend in the X direction and are arranged at certain intervals along the Y direction in such a manner to face the respective flexible beams 42 of the corresponding springs 40.

The electrostatic chuck 70 includes an electrode pad 75 disposed on the substrate 10. The electrode pad 75 is electrically connected to a wiring layer 76 extending over the isolation joint 73. The wiring layer 76 is electrically connected to the electrode part 72 through a via 77 that penetrates the insulating layer 11 in the Z direction. The electrode pad 75 is electrically connected to the electrode part 72 through the wiring layer 76 and the via 77. The electrode pad 75 is disposed on the insulating layer 11, and the electrode pad 75 and the substrate 10 are electrically insulated from each other by the insulating layer 11. When a voltage differing from the voltage applied to the flexible beam 42 of the opposing spring 40 is applied to the electrode part 72 of the electrostatic chuck 70 via the electrode pad 75, an electrostatic force is generated between the electrode part 72 of the electrostatic chuck 70 and the flexible beam 42 of the opposing spring 40, causing the electrode part 72 and the flexible beam 42 to attract each other.

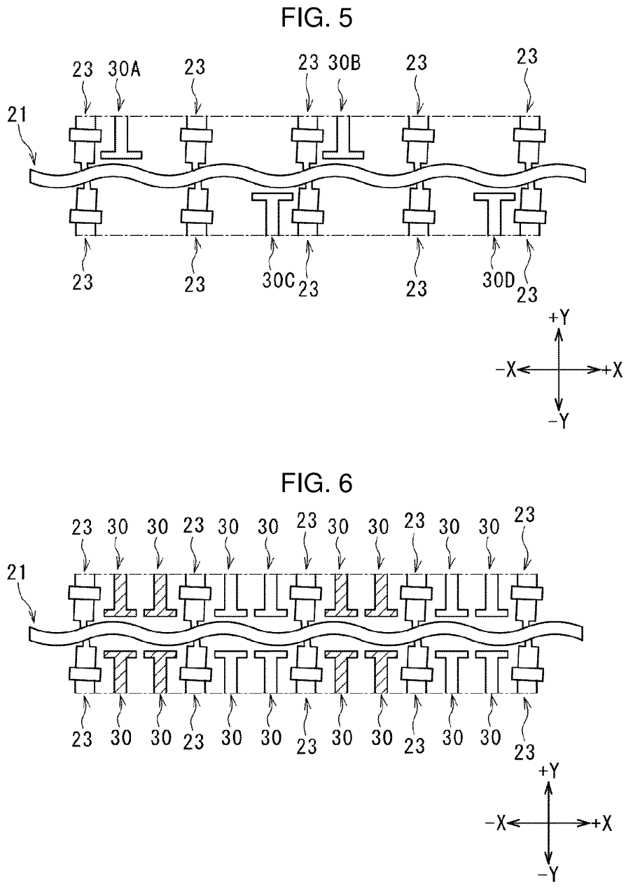

FIG. 5 is a schematic diagram for explaining the operation of the MEMS vibrator 1 of this embodiment. Referring to FIG. 5, when a constant voltage is applied to the vibrating body 21 and an AC voltage is applied to the electrode parts 31 of the fixed electrodes 30A and 30B, the electrostatic force acting on the vibrating body 21 and the electrode parts 31 of the fixed electrodes 30A and 30B causes the vibrating body 21 to vibrate at the resonant frequency of the vibrating body 21. When the vibrating body 21 vibrates, the distance between the vibrating body 21 and the electrode parts 31 of the fixed electrodes 30C and 30D changes, causing the capacitance of the capacitor formed by the vibrating body 21 and the electrode parts 31 of the fixed electrodes 30C and 30D to change. Due to this change in capacitance, an electrical signal having the same frequency as the resonance frequency of the vibrating body 21 is taken out as an output from the electrode pad 35.

### Effects

According to the MEMS vibrator 1 of the embodiments of the present disclosure, the following effects are achieved.

(1) A MEMS vibrator 1 includes:
a substrate 10 having a first primary surface 10a and a second primary surface 10b disposed on the opposite side of the first primary surface 10a, the substrate 10 having a cavity 12 recessed from the first primary surface 10a to the second primary surface 10b;
a vibrating body 21 disposed inside the cavity 12, extending linearly in a first direction (X direction in this embodiment) along the plane in a plan view of the first primary surface 10a, and vibrating in a second direction (Y direction in this embodiment) that intersects with the first direction along the plane; and
a plurality of supports 23 disposed inside the cavity 12, supporting the vibrating body 21 from the second direction at a plurality of supporting positions arranged along the first direction at a certain interval.

The resonance frequency of the MEMS vibrator is determined mainly by the dimensions of the vibrating body in the vibrating direction thereof. In the case of a MEMS vibrator having a vibrating body that is a thin film layer provided on a substrate and vibrates in the thickness direction of the substrate, the vibrating body is manufactured by the thin-film deposition method. In general, the thin-film deposition method requires more precise control on the film thickness than etching where film thickness is controlled by the pattern dimensions. In contrast, in this configuration, the vibrating body 21 vibrates in the Y direction that extends along the plane in a plan view of the first primary surface 10a of the substrate 10. In other words, the vibrating direction of the vibrating body 21 is perpendicular to the thickness direction of the substrate 10, and therefore, the dimensions of the vibrating body 21 in the vibrating direction can be controlled as the pattern dimensions in etching. As a result, the MEMS vibrator 1 having a desired resonant frequency can be manufactured without the need for precise control.

(2) The plurality of supports 23 support the vibrating body 21 over the entire length of the vibrating body 21 in a thickness direction (Z direction in this embodiment) of the substrate 10 at corresponding supporting positions, respectively.

With this configuration, displacement of the vibrating body 21 is restricted over the entire length in the Z direction at each supporting position, and therefore, it is possible to prevent the vibrating body 21 from vibrating in an unintended manner.

(3) The vibrating body 21 includes a main body 21a made of silicon and a deformation stopper 21b disposed within the main body 21a and having a thermal expansion coefficient smaller than that of the main body 21a.

With this configuration, because the deformation stopper 21b having a thermal expansion coefficient smaller than that of the main body 21a is disposed in the main body 21a, changes in dimension of the vibrating body 21 due to changes in temperature can be suppressed. This makes it possible to prevent the resonance frequency of the MEMS vibrator 1 from fluctuating due to changes in temperature.

(4) The MEMS vibrator 1 includes: an electrode part 31 disposed to face the vibrating body 21 in the second direction (Y direction in this embodiment) and configured to cause the vibrating body 21 to vibrate; an anchor 32 fixed to the substrate 10 to support the electrode part 31; and a connecting part 33 that connects the electrode part 31 to the anchor 32. The connecting part 33 has a first portion 42a having a first thermal coefficient, and a second portion 42b disposed adjacent to the first portion 42a in the second direction and having a second thermal expansion coefficient that differs from the first thermal coefficient. The connecting part 33 is deformed due to a difference between the thermal stress generated in the first portion 42a and the thermal stress generated in the second portion 42b, and as a result of the deformation of the connecting part 33, a gap between the vibrating body 22 and the electrode part 31 becomes narrower than the gap before the deformation.

In an electrostatic resonator, the shorter the distance between the vibrating body 21 and the electrode part 31, the greater the amplitude of the electrical signal obtained as the output. However, since there is a limit to the aspect ratio of etching, the gap between the vibrating body 21 and the electrode part 31 increases as the etching depth increases. In other words, when etching is performed to a prescribed depth between the vibrating body 21 and the electrode part 31, it might be difficult to make the gap between the vibrating body 21 and the electrode part 31 narrower than a certain gap. In contrast, with this configuration, the connecting part 33 is deformed due to the difference between the thermal stress generated in the first portion 42a and the thermal stress generated in the second portion 42b, and this deformation of the connecting part 33 makes the gap between the vibrating body 21 and the electrode part 31 narrower than the gap before the connecting part 33 was deformed. That is, the gap between the vibrating body 21 and the electrode part 31 can be made narrower than the gap formed between the vibrating body 21 and the electrode part 31 by etching to form the vibrating body 21 and the electrode part 31. As a result, the gap between the vibrating body 21 and the electrode part 31 can be narrowed regardless of the limit of the aspect ratio of etching, which can improve the amplitude of the electric signal obtained as the output of the MEMS vibrator 1.

(5) The MEMS vibrator 1 includes a restricting part 60 that restricts displacement of the electrode part 31 by making contact with the connecting part 33 when the electrode part 31 moves by a prescribed distance toward the vibrating body 21 as a result of the deformation of the connecting part 33.

With this configuration, the restricting part 60 suppresses the displacement of the electrode part 31 in the Y direction, and therefore, the distance between the vibrating body 21 and the electrode part 31 can be maintained at a prescribed distance regardless of manufacturing errors or temperature changes.

(6) The MEMS vibrator 1 includes an electrostatic chuck 70 disposed to face the connecting part 33 in the second direction (Y direction in this embodiment) and configured to generate an electrostatic force acting on the connecting part 33 upon receiving a voltage that differs from a voltage applied to the electrode part 31 and pull the connecting part 33 such that the electrode part 31 moves toward the vibrating body 21.

By generating an electrostatic force that attracts the electrode part 31 and the connecting part 33 to each other, it is possible to prevent the distance between the vibrating body 21 and the electrode part 31 from unintentionally changing, even if, for example, vibration or impact is applied to the MEMS vibrator 1 while the restricting part 60 and the connecting part 33 are in contact.

### MODIFICATION EXAMPLES

The MEMS vibrator according to the present disclosure is not limited to the configurations of the embodiment described above, and may be modified in various manners.

FIG. 6 is a diagram similar to FIG. 5 according to a modification example of the embodiment described above. In FIG. 6, the fixed electrodes 30 that function as drive electrodes are hatched to distinguish them from the fixed electrodes 30 that function as detection electrodes. In the modification example of FIG. 6, a pair of fixed electrodes 30, 30 are disposed at each side of the vibrating body 22 in the Y direction. In the modification example of FIG. 6, a plurality of pairs of fixed electrodes 30, 30 are arranged along the X direction. AC voltages of opposite phases are applied to the pair of fixed electrodes 30, 30 that function as drive electrodes, respectively. The MEMS vibrator 1 of the modification example shown in FIG. 6 is a differential drive type MEMS resonator. Also, the same constant voltage is applied to the pair of fixed electrodes 30, 30 that function as detection electrodes. The MEMS vibrator 1 of the modification example shown in FIG. 6 is a differential detection type MEMS resonator.

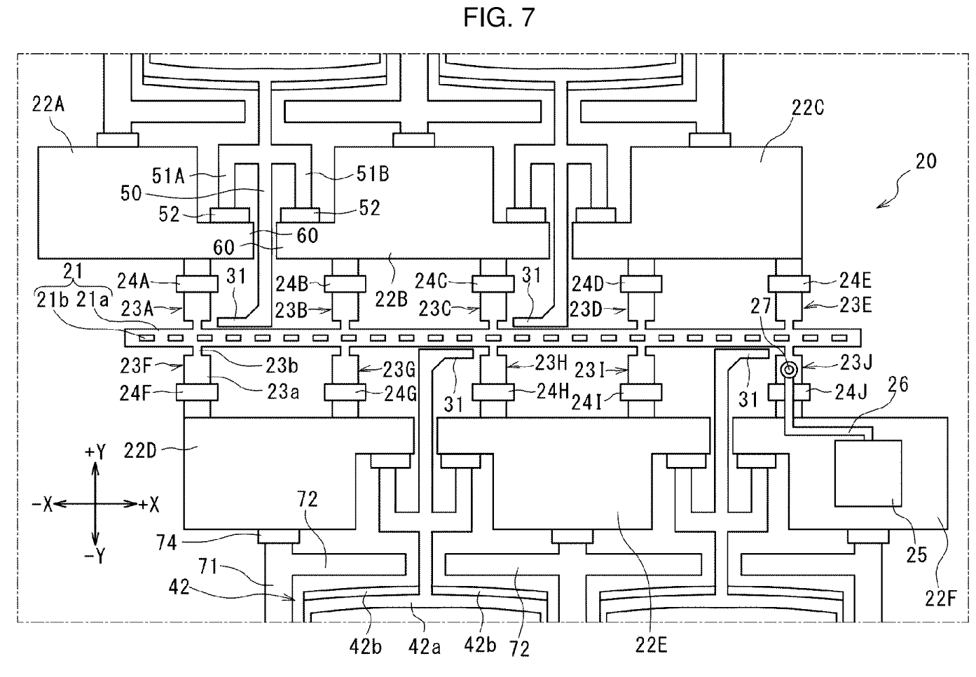

In the embodiment above, the deformation stopper 21b extends continuously in the X direction within the main body 21a, but the present disclosure is not limited to this. A plurality of parts of the deformation stopper 21b may be arranged at certain intervals in the X direction, as in the modification example shown in FIG. 7.

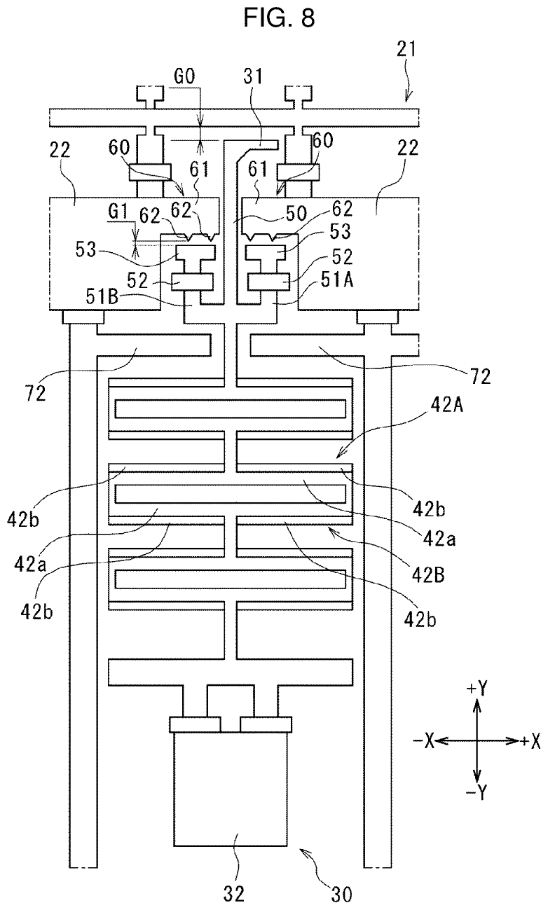

FIG. 8 is a diagram similar to FIG. 4 according to yet another modification example of the embodiment described above. In the modification example of FIG. 8, the insulator 52 of the beam 50 is an isolation joint that traverses the corresponding protrusion 51 in the X and Z directions and separates the corresponding protrusion 51 in the Y direction. In the modification example of FIG. 8, the insulator 52 mechanically connects and electrically insulates both sides of the corresponding protrusion 51 that are separated in the Y direction by the insulator 52. At the tip of each of the protrusions 51A and 51B shown in FIG. 8, a tip portion 53 is disposed facing the restricting part 60 in the Y direction and extending in the X direction. The tip portion 53 is made of conductive silicon.

In the modification example of FIG. 8, the restricting part 60 includes a main body 61 protruding in the X direction from the anchor 22 of the vibrating electrode 20, and a stopper 62 protruding from the main body 61 toward the tip portion 53. The stopper 62 has a triangular shape tapered toward the tip portion 53 in a plan view as shown in FIG. 8. The stopper 62 is not limited to a triangular shape, and may have other shapes such as a trapezoidal shape tapering toward the tip portion 53 in a plan view. In the modification example of FIG. 8, the gap between the tip of the stopper 62 and the tip portion 53 formed in the etching process to form the restricting part 60 and beam 50 is narrower than the gap G0 between the vibrating body 21 and electrode portion 31 formed in the etching process to form the vibrating body 21 and electrode part 31.

It is difficult to make the gap between the main body 61 and the tip portion 53 formed in the etching process narrower than a prescribed gap due to the limit of the etching aspect ratio. Therefore, in order to make the gap formed by etching between the main body 61 and the tip portion 53 narrower than the gap formed by etching between the vibrating body 21 and the electrode part 31, it is necessary to widen the gap formed between the vibrating body 21 and the electrode part 31 more than necessary. That is, the gap formed between the vibrating body 21 and the electrode part 31 needs to be wider than the smallest gap possible that can be formed between the vibrating body 21 and the electrode part 31 by etching. On the other hand, the stopper 62 that partially protrudes from the main body 61 can be manufactured regardless of the limit of the etching aspect ratio. Therefore, in the modification example of FIG. 8, regardless of the limit of the etching aspect ratio, it is possible to make the gap G0 formed by etching between the stopper 62 and the tip portion 53 narrower than the gap G0 formed by etching between the vibrating body 21 and the electrode part 31. In this way, by providing the stopper 62 that protrudes from the main body 61 toward the tip portion 53, the distance that the tip portion 53 moves when the electrode part 31 deforms to approach the vibrating body 21 due to deformation of the spring 40 can be made shorter compared to the configuration in which the stopper 62 is not provided.

According to the MEMS vibrator 1 of the modification example of FIG. 8, the gap G1 formed by etching between the restricting part 60 and the tip portion 53 can be made narrower than the gap G0 formed by etching between the vibrating body 21 and the electrode part 31. Therefore, when the deformation of the spring 40 causes the electrode part 31 to move closer to the vibrating body 21, the stopper 62 comes into contact with the tip portion 53 before the vibrating body 21 and the electrode part 31 come into contact, thereby preventing the electrode part 31 and the vibrating body 21 from making contact with each other. As a result, it is possible to prevent the vibrating body 21 from coming into contact with the electrode part 31 while ensuring a desired distance between the vibrating body 21 and the electrode part 31.

In the embodiment described above, an electrostatic resonator has been described as an example of a MEMS vibrator according to the present disclosure, but the MEMS vibrator according to the present disclosure may also be applied to a filter, an oscillator, a temperature sensor, a mass sensor, a temperature sensor, a gyro sensor, or a motion sensor.

### Supplementary Notes

A MEMS vibrator according to the present disclosure provides the following aspects.

### Aspect 1

A MEMS vibrator, including:
a substrate having a first primary surface and a second primary surface disposed on the opposite side of the first primary surface, the substrate having a cavity recessed from the first primary surface toward the second primary surface;
a vibrating body disposed inside the cavity, extending linearly in a first direction along the plane in a plan view of the first primary surface, and vibrating in a second direction that intersects with the first direction along the plane; and
a plurality of supports disposed inside the cavity, supporting the vibrating body from the second direction at a plurality of supporting positions arranged along the first direction at a certain interval.

### Aspect 2

The MEMS vibrator according to Aspect 1, wherein the plurality of supports support the vibrating body over the entire length of the vibrating body in a thickness direction of the substrate at corresponding supporting positions, respectively.

### Aspect 3

The MEMS vibrator according to Aspect 1 or 2, wherein the vibrating body includes:
a main body made of silicon; and
a deformation stopper disposed inside the main body and having a smaller thermal expansion coefficient than that of the main body.

### Aspect 4

The MEMS vibrator according to any one of Aspects 1 to 3,
an electrode part that is disposed to face the vibrating body in the second direction and that causes the vibrating body to vibrate;
an anchor fixed to the substrate to support the electrode part; and
a connecting part connecting the electrode part to the anchor,
wherein the connecting part includes:
   a first portion having a first thermal expansion coefficient; and
   a second portion disposed adjacent to the first portion in the second direction and having a second thermal expansion coefficient that differs from the first thermal coefficient, and
wherein the connecting part is deformed due to a difference between thermal stress generated in the first portion and thermal stress generated in the second portion, and as a result of the deformation of the connecting part, a gap between the vibrating body and the electrode part becomes narrower than that before the deformation.

### Aspect 5

The MEMS vibrator according to Aspect 4, further including a restricting part that restricts displacement of the electrode part by making contact with the connecting part when the electrode part moves by a prescribed distance toward the vibrating body as a result of the deformation of the connecting part.

### Aspect 6

The MEMS vibrator according to Aspect 5, further including an electrostatic chuck disposed to face the connecting part in the second direction and configured to generate an electrostatic force acting on the connecting part upon receiving a voltage that differs from a voltage applied to the electrode part and pull the connecting part such that the electrode part moves toward the vibrating body.

What is claimed is:

1. A MEMS (micro electromechanical system) vibrator, including:
a substrate having a first primary surface and a second primary surface disposed on an opposite side of the first primary surface, the substrate having a cavity recessed from the first primary surface toward the second primary surface;
a vibrating body disposed inside the cavity, extending linearly in a first direction along a plane in a plan view of the first primary surface, and vibrating in a second direction that intersects with the first direction along the plane; and
a plurality of supports disposed inside the cavity, supporting the vibrating body from the second direction at a plurality of supporting positions arranged along the first direction at a certain interval.

2. The MEMS vibrator according to claim 1, wherein the plurality of supports support the vibrating body over an entire length of the vibrating body in a thickness direction of the substrate at corresponding supporting positions, respectively.

3. The MEMS vibrator according to claim 1, wherein the vibrating body includes:
a main body made of silicon; and
a deformation stopper disposed inside the main body and having a smaller thermal expansion coefficient than a thermal expansion coefficient of the main body.

4. The MEMS vibrator according to claim 1, further comprising:
an electrode part that is disposed to face the vibrating body in the second direction and that causes the vibrating body to vibrate;
an anchor fixed to the substrate to support the electrode part; and
a connecting part connecting the electrode part to the anchor,
wherein the connecting part includes:
a first portion having a first thermal expansion coefficient; and
a second portion disposed adjacent to the first portion in the second direction and having a second thermal expansion coefficient that differs from the first thermal coefficient, and
wherein the connecting part is deformable due to a difference between thermal stress generated in the first portion and thermal stress generated in the second portion, and as a result of a deformation of the connecting part, a gap between the vibrating body and the electrode part becomes narrower than the gap before the deformation.

5. The MEMS vibrator according to claim 4, further comprising a restricting part that restricts displacement of the electrode part by making contact with the connecting part when the electrode part moves by a prescribed distance toward the vibrating body as a result of the deformation of the connecting part.

6. The MEMS vibrator according to claim 5, further comprising an electrostatic chuck disposed to face the connecting part in the second direction and configured to generate an electrostatic force acting on the connecting part upon receiving a voltage that differs from a voltage applied to the electrode part and pull the connecting part such that the electrode part moves toward the vibrating body.
